(19) United States
(12) Patent Application Publication
(10) Pub. No.: US 2018/0114874 A1
(43) Pub. Date: Apr. 26, 2018

(54) PHOTOELECTRIC CONVERSION DEVICE

(71) Applicant: KYOCERA CORPORATION, Kyoto-shi, Kyoto (JP)

(72) Inventor: Junji ARANAMI, Otsu-shi (JP)

(21) Appl. No.: 15/558,678

(22) PCT Filed: Mar. 22, 2016
(86) PCT No.: PCT/JP2016/058991

§ 371 Date: Sep. 15, 2017

(30) Foreign Application Priority Data
Mar. 25, 2015 (JP) 2015-062465

(51) Int. Cl. H01L 31/0749; H01L 31/036; H01L 31/0352; H01L 31/074; H01L 51/42; H01L 51/00

(52) U.S. Cl. CPC H01L 31/0749; H01L 31/036; H01L 31/035272; H01L 31/022425; H01L 51/4213; H01L 51/0077; H01L 31/074

(57) ABSTRACT

A photoelectric conversion device according to an embodiment of the present invention includes an electrode layer, a first semiconductor layer, a second semiconductor layer, and an intermediate layer. The first semiconductor layer is located over the electrode layer. The first semiconductor layer has p-type or i-type conductivity and includes primarily a chalcopyrite-type compound or a perovskite-type compound. The second semiconductor layer has n-type conductivity and located over the first semiconductor layer. The intermediate layer is located at an interface between the electrode layer and the first semiconductor layer. The intermediate layer includes primarily a semiconductor having p-type conductivity and having a crystal structure different from a crystal structure of the first semiconductor layer. The intermediate layer has a carrier concentration greater than a carrier concentration of the first semiconductor layer.

### TECHNICAL FIELD

The present invention relates to a photoelectric conversion device including a compound semiconductor layer.

### BACKGROUND ART

Some photoelectric conversion devices that can be used for, for example, photovoltaic generation include a compound semiconductor layer including, for example, a chalcopyrite-type compound. The compound semiconductor layer serves as a light-absorbing layer (see, for example, Patent Literature 1). In such a photoelectric conversion device, a plurality of photoelectric cells are arranged in a plane. Each of the photoelectric cells includes a lower electrode, such as a metal electrode, a light-absorbing layer including a metal chalcogenide, such as copper indium gallium selenide (CIGS), a buffer layer including indium sulfide and forming a heterojunction with the light-absorbing layer, and an upper electrode, such as a transparent electrode or a metal electrode. These layers are stacked over a substrate, such as a glass substrate, in the order mentioned. The plurality of photoelectric cells are electrically connected to one another in series in such a manner that the upper electrode of one photoelectric cell is electrically connected to the lower electrode of another photoelectric cell adjacent thereto via a connection conductor (see Japanese Unexamined Patent Application Publication No. 2003-282909).

### SUMMARY OF INVENTION

A photoelectric conversion device according to an embodiment of the present invention includes an electrode layer, a first semiconductor layer, a second semiconductor layer, and an intermediate layer. The first semiconductor layer is located over the electrode layer. The first semiconductor layer has p-type or i-type conductivity and includes primarily a chalcopyrite-type compound or a perovskite-type compound. The second semiconductor layer has n-type conductivity and is located over the first semiconductor layer. The intermediate layer is located at an interface between the electrode layer and the first semiconductor layer. The intermediate layer includes primarily a semiconductor having p-type conductivity and having a crystal structure different from a crystal structure of the first semiconductor layer. The intermediate layer has a carrier concentration greater than a carrier concentration of the first semiconductor layer.

### BRIEF DESCRIPTION OF DRAWINGS

FIG. 1 is a perspective view of a photoelectric conversion device according to a first embodiment.

FIG. 2 is a sectional view of the photoelectric conversion device in FIG. 1.

FIG. 3 is a perspective view of a photoelectric conversion device according to a second embodiment.

FIG. 4 is a sectional view of the photoelectric conversion device in FIG. 3.

FIG. 5 is a top view of the photoelectric conversion device in FIG. 3 with a first semiconductor layer and layers over it removed.

FIG. 6 is a perspective view of a photoelectric conversion device according to a third embodiment.

FIG. 7 is a sectional view of the photoelectric conversion device in FIG. 6.

### DESCRIPTION OF EMBODIMENTS

Embodiments of a photoelectric conversion device according to the present disclosure will now be described in detail with reference to the drawings.

### Photoelectric Conversion Device According to First Embodiment

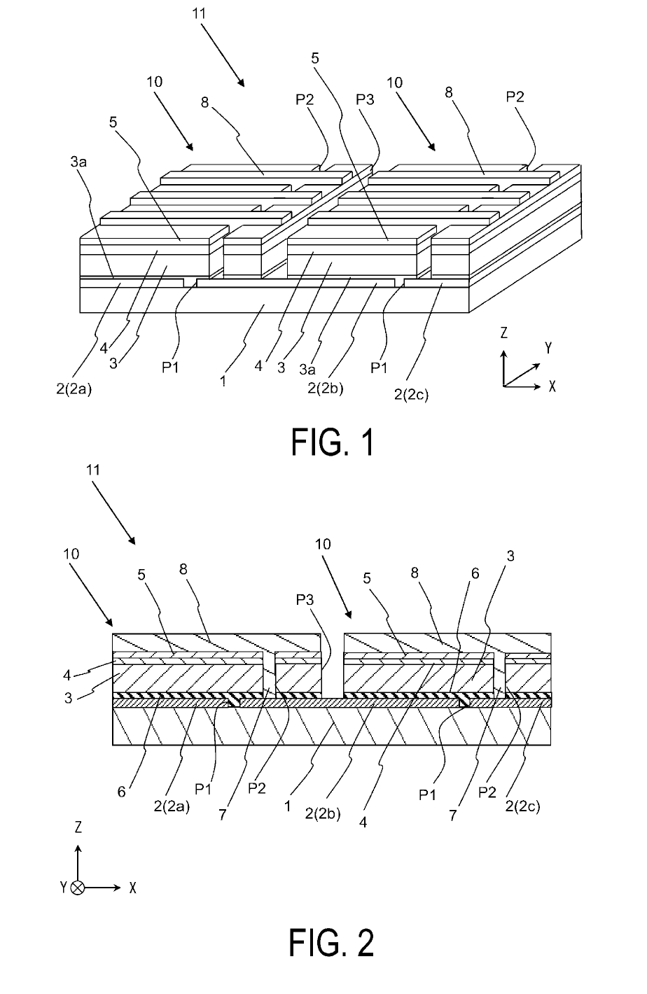

FIG. 1 is a perspective view of a photoelectric conversion device according to a first embodiment, and FIG. 2 is a sectional view thereof. The photoelectric conversion device 11 includes a plurality of photoelectric cells 10 on a substrate 1. The photoelectric cells 10 are spaced from one another with a spacing P3, and adjacent photoelectric cells 10 are electrically connected to each other. Although FIG. 1 illustrates only two photoelectric cells 10 for illustration purposes, a practical photoelectric conversion device 11 may include a large number of photoelectric cells 10, arranged in a plane (in two dimensions) in the left and right direction in the drawing or, in addition to this, in a direction perpendicular thereto.

In FIGS. 1 and 2, a plurality of electrode layers 2 are disposed in a plane over the substrate 1. Each electrode layer 2 is connected adjacent to the first semiconductor layer 3. In the description below, the electrode layer 2 will be referred to as lower electrode layer 2 to distinguish it from an upper electrode layer 5, which will be described later. However, the lower electrode layer 2 may not necessarily be located below the upper electrode layer 4, and may be located thereabove.

In FIGS. 1 and 2, the plurality of lower electrode layers 2 include lower electrode layers 2a to 2c, which are arranged in a direction with a spacing P1 therebetween. Over the lower electrode layer 2a and the lower electrode layer 2b, with the substrate 1 therebetween, the first semiconductor layer 3, a buffer layer 4, and the upper electrode layer 5 are stacked in the order mentioned. Over the lower electrode layer 2b, a connection conductor 7 is disposed along or through the side surfaces of the first semiconductor layer 3 and the buffer layer 4. The connection conductor 7 electrically connects the upper electrode layer 5 to the lower electrode layer 2b. An intermediate layer 3a is disposed at the interface between the lower electrode layer 2 and the first semiconductor layer 3. The lower electrode layer 2, the intermediate layer 3a, the first semiconductor layer 3, the buffer layer 4, and the upper electrode layer 5 constitute a photoelectric cell 10, and adjacent photoelectric cells 10 are connected to each other in series via the connection conductor 7 to form the photoelectric conversion device 11, which has high output. The photoelectric conversion device 11 according to the embodiment is described on the assumption that incident light enters the first semiconductor layer 3 from the upper electrode layer 5 side, but this is not limiting. Incident light may enter the first semiconductor layer 3 from the lower electrode layer 2 side.

The substrate 1 supports the photoelectric cells 10. Examples of the material of the substrate 1 include glass, ceramics, resins, and metals. For example, the substrate 1 may be a soda-lime glass substrate having a thickness of approximately 1 to 3 mm.

The lower electrode layer 2 (lower electrode layers 2a, 2b, 2c) is disposed over the substrate 1 and includes a conductive material such as Mo, Al, Ti, or Au. The lower electrode layer 2 is formed by a known thin-film deposition process such as sputtering or vapor deposition, to have a thickness of approximately 0.2 μm to 1 μm.

The first semiconductor layer 3 is a semiconductor layer serving to absorb light and generate carriers (electrons and holes), and thus it is a so-called light-absorbing layer. The first semiconductor layer 3 is, for example, a p-type or an i-type semiconductor layer having a thickness of approximately 1 μm to 3 μm. The first semiconductor layer 3 includes primarily a chalcopyrite-type compound or primarily a perovskite-type compound. The phrase “includes primarily a chalcopyrite-type compound” means including a chalcopyrite-type compound in an amount of greater than or equal to 70 mol %. The phrase “includes primarily a perovskite-type compound” means including a perovskite-type compound in an amount of greater than or equal to 70 mol %.

The chalcopyrite-type compound is a compound of chalcopyrite structure, and examples thereof include Group compounds. The Group compound is a compound of a Group 11 element (also known as Group I-B element), a Group 13 element (also known as a Group III-B element), and a Group 16 element. Examples of the Group compound include CuInSe₂ (copper indium diselenide, also known as CIS), Cu(In,Ga)Se₂ (copper indium gallium diselenide, also known as CIGS), and Cu(In,Ga)(Se,S)₂ (copper indium gallium diselenide/sulfide, also known as CIGSS). Alternatively, the first semiconductor layer 3 may be a multi compound semiconductor thin film of, for example, copper indium gallium diselenide with a thin surface layer of copper indium gallium diselenide/sulfide.

The perovskite-type compound is a compound of perovskite structure, and examples thereof include organic-inorganic composite materials such as CH₃NH₃PbX₃ (where X is a halogen). The organic-inorganic composite material is a material in which organic components and inorganic components are combined at the molecular level. The perovskite-type compound may be a compound not including organic matter, such as APbX₃ (where A is an alkali metal such as Cs and X is a halogen). Suitable examples of the material encompassed by the present disclosure include Pb-containing perovskite-type compounds in which X is a halogen. Furthermore, the halogen, denoted by X, may be two or more halogens. The organic matter, e.g., CH₃NH₃, may be two or more types of organic matter. The alkali metal, e.g., Cs, may be two or more alkali metals. By mixing a plurality of materials as described above, desired bandgaps, thermal resistance, and withstand voltage are achieved. As a result, perovskite-type photovoltaic cells that can be suitably made into a tandem structure and photovoltaic cells that provide high process flexibilities and have excellent long-term reliability can be obtained.

The first semiconductor layer 3 can be formed by a so-called vacuum process such as sputtering or vapor deposition or by a process known as coating or printing. The process known as coating or printing is a process in which a complex solution of the elements constituting the first semiconductor layer 3 is applied over the intermediate layer 3a or the lower electrode layer 2 and is then dried and heated.

The intermediate layer 3a is located at the interface between the lower electrode layer 2 and the first semiconductor layer 3. That is, the first semiconductor layer 3 is electrically connected to the lower electrode layer 2 via the intermediate layer 3a. The intermediate layer 3a includes a semiconductor having p-type conductivity and having a crystal structure different from the crystal structure of the first semiconductor layer 3, and has a carrier concentration greater than the carrier concentration of the first semiconductor layer 3. The intermediate layer 3a has a thickness of approximately 30 to 2000 nm.

This configuration reduces recombination of carriers generated by photoelectric conversion by the first semiconductor layer 3 and thus improves the photoelectric conversion efficiency of the photoelectric conversion device 11. Specifically, a strong electric field is applied via the intermediate layer 3a to the charge-separated carriers in the first semiconductor layer 3 so that the effect of extracting carriers is enhanced. As a result, recombination of carriers is reduced and the conversion efficiency is increased.

For chalcopyrite-type compounds and perovskite-type compounds, dopant control is difficult, and therefore controlling the carrier concentration to a desired concentration with low defects is difficult. Thus, the carrier concentration of the first semiconductor layer 3 may be, for example, approximately less than or equal to 1×10¹⁰ to 9×10¹⁷ cm⁻³ in order to prevent an increase in recombinations due to defects. The intermediate layer 3a has a carrier concentration of, for example, 1×10¹⁸ to 9×10¹⁸ cm⁻³, which is higher than the carrier concentration of the first semiconductor layer 3, and because of this, charge-separated carriers can be easily extracted from the first semiconductor layer 3. The intermediate layer 3a includes a semiconductor having p-type conductivity and having a crystal structure different from the crystal structure of the first semiconductor layer 3 so that dopant control in a low-defect state can be facilitated.

The intermediate layer 3a may include, for example, a semiconductor including primarily silicon (Si) doped with another element such as boron (B). The phrase “including primarily Si” means including Si in an amount of greater than or equal to 70 mol %. An alternative intermediate layer 3a may include a compound semiconductor such as zinc selenide, which can be easily joined to the first semiconductor layer 3.

Examples of film deposition processes for forming the intermediate layer 3a include vapor deposition, sputtering, sol-gel processing, screen printing, coating, plating, spray coating, ink jet coating, chemical vapor deposition (CVD), plasma chemical vapor deposition (CVD), and physical vapor deposition (PVD). Optionally, in addition to the above, a pattern-forming process may be employed to form the intermediate layer 3a to a desired pattern. Examples of the process include photolithography, lift-off, coating using a dispenser, and laser scribing.

A second semiconductor layer is a semiconductor layer having n-type conductivity, different from that of the first semiconductor layer 3, and forms a pn junction with the first semiconductor layer 3. In the photoelectric conversion device 11 according to the first embodiment, an example of the second semiconductor layer is a laminate of the buffer layer 4 and the upper electrode layer 5, but this is not limiting. The second semiconductor layer may be a single layer or a laminate of three or more layers. In the case where the second semiconductor layer includes a plurality of layers, at least one layer among the plurality of layers may be of n-type. That is, the second semiconductor layer may be a laminate of an n-type semiconductor layer and an i-type semiconductor layer or a laminate of n-type semiconductor layers.

The buffer layer 4 is an n-type or an i-type semiconductor layer forming a heterojunction with the first semiconductor layer 3. The buffer layer 4 has a thickness of 5 to 200 nm, for example. Examples of the buffer layer 4 include layers of a metal sulfide such as CdS, ZnS, and In₂S₃. The buffer layer 4 may be a mixed crystal including, in addition to a metal sulfide, at least one among a metal oxide and a metal hydroxide. The buffer layer 4 is formed, for example, by chemical bath deposition (CBD), atomic layer deposition (ALD), or metal organic chemical vapor deposition (MOCVD).

In the case where the first semiconductor layer 3 includes primarily a perovskite-type compound, the buffer layer 4 may include an n-type organic semiconductor. Examples of the organic semiconductor include fullerene derivatives such as phenyl-C₆₁-butyric acid methyl ester (PCBM) and fullerene C60. In the case where an organic semiconductor is to be included in the buffer layer 4, the buffer layer 4 may be formed, for example, by dissolving PCBM, for example, in an organic solvent and applying the solution to the first semiconductor layer 3 and then drying the solution. Alternatively, the buffer layer 4 may be formed by vapor depositing fullerene C60, for example, over the first semiconductor layer 3. In order for the first semiconductor layer 3 or the buffer layer 4 to be less susceptible to the influence from the process of forming the upper electrode layer 5, which will be described later, a protective buffer layer, in addition, may be stacked over the buffer layer 4. The protective buffer layer may include, for example, molybdenum oxide or tungsten oxide. The protective buffer layer may be formed by sputtering or vapor deposition, for example.

The upper electrode layer 5 is an n-type semiconductor layer and a conductive film having a thickness of approximately 0.05 to 3.0 μm. The upper electrode layer 5 is provided to sufficiently extract carriers generated in the first semiconductor layer 3. For example, the electrical resistivity of the upper electrode layer 5 may be less than or equal to 1 Ω·cm and the sheet resistivity thereof may be less than or equal to 50 Ω/□.

The upper electrode layer 5 may include, for example, a metal oxide such as ZnO, In₂O₃, or SnO₂, and in order to reduce the electrical resistivity, may include any of the following elements: Al, B, Ga, In, Sn, and F, for example. Specific examples of the metal oxide semiconductor including any of the above elements include aluminum zinc oxide (AZO), boron zinc oxide (BZO), gallium zinc oxide (GZO), indium zinc oxide (IZO), indium tin oxide (ITO), and fluorine tin oxide (FTO). The upper electrode layer 5 is formed by sputtering, vapor deposition, or CVD, for example.

In the case where the buffer layer 4 includes an n-type organic semiconductor, the upper electrode layer 5 may include a metal such as gold, silver, and copper, for example. In this case, the upper electrode layer 5 may be made to be sufficiently thin to enable light to be transmitted therethrough, or a configuration may be employed such that the lower electrode layer 2 includes a light transmissive material and incident light can enter the first semiconductor layer 3 from the substrate 1 side. When the upper electrode layer 5 includes a metal and the configuration such that incident light can enter from the substrate 1 side is employed, as described above, the optical path length is extended because of light reflection on the upper electrode layer 5 and, as a result, the light absorption is improved to increase the conversion efficiency.

In addition, a collector electrode 8 may be formed over the upper electrode layer 5 as illustrated in FIGS. 1 and 2. The collector electrode 8 is provided to more sufficiently extract carriers generated in the first semiconductor layer 3. For example, as illustrated in FIG. 1, the collector electrode 8 extends linearly from one end of the photoelectric cell 10 and over the connection conductor 7. Thus, the electrical current generated in the first semiconductor layer 3 is collected by the collector electrode 8 via the upper electrode layer 5, and the current flows sufficiently to an adjacent photoelectric cell 10 via the connection conductor 7.

The collector electrode 8 may have a width of 50 to 400 μm in order to increase the transmittance of light to the first semiconductor layer 3 and to have good electrical conductivity. The collector electrode 8 may have a plurality of branch portions that are branched.

The collector electrode 8 is formed, for example, by printing a metal paste in a pattern and curing the paste. The metal paste may include a metal powder, such as a Ag powder, dispersed in a resin binder, for example.

Referring to FIGS. 1 and 2, the connection conductor 7 is a conductor disposed in a trench P2. The trench P2 divides the first semiconductor layer 3, the buffer layer 4, and the upper electrode layer 5. The connection conductor 7 may be formed from a metal or a conductive paste, for example. In FIGS. 1 and 2, the connection conductor 7 is an extension of the collector electrode 8, but this is not limiting. For example, it may be an extension of the upper electrode layer 5.

The invention is not limited to the above-described embodiment, and various modifications, improvements and the like may be made to the embodiment without departing from the scope of the invention. In the following, various modified examples are described.

### Photoelectric Conversion Device According to Second Embodiment

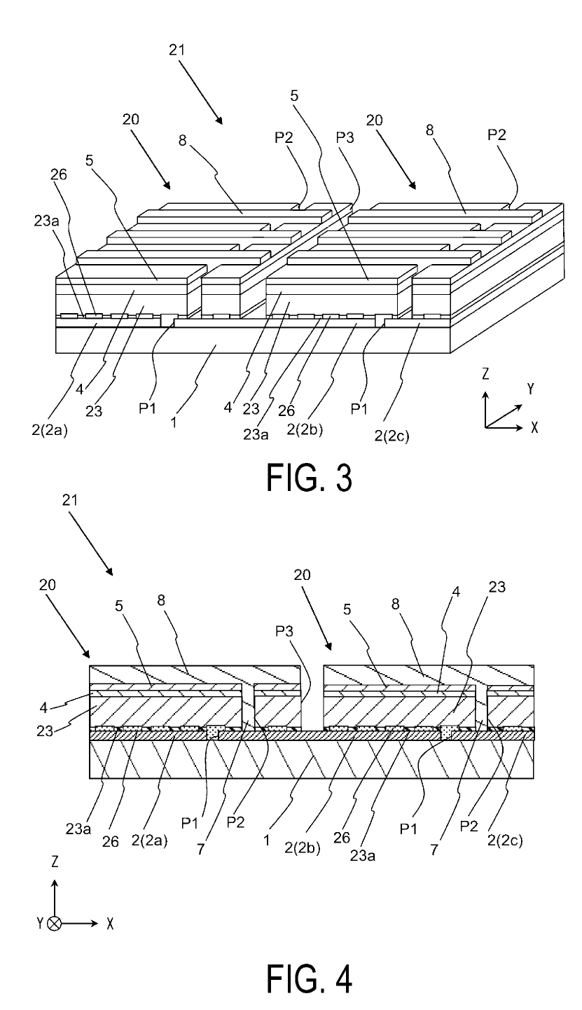

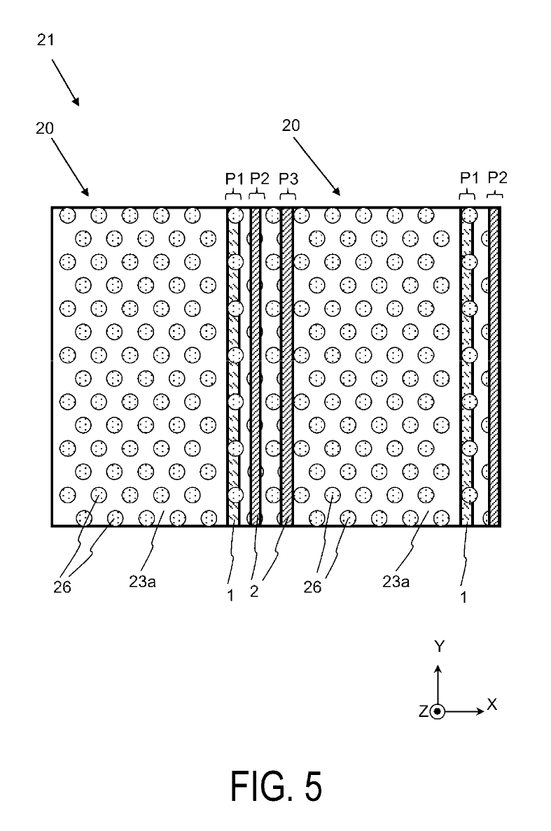

FIG. 3 is a perspective view of a photoelectric conversion device 21 according to a second embodiment, and FIG. 4 is a sectional view thereof. FIG. 5 is a top view of the photoelectric conversion device 21 with a first semiconductor layer 23 and layers over it removed so that the top view configurations of an intermediate layer 23a and an insulating layer 26 can be easily seen. In the photoelectric conversion device 21 according to the second embodiment, the same parts as those in the photoelectric conversion device 11 according to the first embodiment are indicated by the same reference signs, and detailed descriptions thereof will not be provided.

In each of the photoelectric cells 20 of the photoelectric conversion device 21 according to the second embodiment, the intermediate layer 23a partially covers the lower electrode layer 2, and the insulating layer 26 is located at the region not covered by the intermediate layer 23a in the lower electrode layer 2. The first semiconductor layer 23 is joined to the intermediate layer 23a and the insulating layer 26.

With this configuration, the insulating layer 26 serves as a passivation film and produces a field effect due to band bending, to thereby reduce recombination of carriers at the surface of the first semiconductor layer 23. At the region where the lower electrode layer 2 and the first semiconductor layer 23 are joined to each other via the intermediate layer 23a, the intermediate layer 23a can sufficiently extract carriers from the first semiconductor layer 3. As a result of the above, the photoelectric conversion efficiency of the photoelectric conversion device 21 is further improved.

As illustrated in FIG. 5, the insulating layer 26 is in the form of a plurality of substantially circular portions spaced from one another in plan view. The insulating layer 26 is not limited to this configuration and, for example, may be in the form of a plurality of substantially linear portions spaced from each other.

The insulating layer 26 may have an electrical resistivity of greater than or equal to 1 Ω·m. The insulating layer 26 may include, for example, a metal oxide such as Al₂O₃, SiO₂, ZrO₂, MgO, and TiO₂, or a heat resistant resin such as a polyimide resin.

When the insulating layer 6 includes at least one among Al₂O₃, SiO₂, ZrO₂, MgO, and TiO₂, the adhesion between the lower electrode layer 2 and the first semiconductor layer 23 increases. In this case, the contents of Al₂O₃, SiO₂, ZrO₂, MgO, and TiO₂ in the insulating layer 6 are preferably such that the total content of Al₂O₃, SiO₂, ZrO₂, MgO, and TiO₂ is greater than or equal to 50 mass % relative to the total mass of the insulating layer 6. When it is intended to further increase the adhesion between the lower electrode layer 2 and the first semiconductor layer 23 and the thermal resistance of the insulating layer 26, the total content of Al₂O₃, SiO₂, ZrO₂, MgO, and TiO₂ is preferably greater than or equal to 70 mass % relative to the total mass of the insulating layer 6.

When the insulating layer 26 includes a polyimide resin, the flexibility of the insulating layer 26 is improved and, as a result, insulation failures (decrease in passivation function) due to, for example, cracking in the insulating layer 26 can be reduced. Furthermore, the insulating layer 26 acts as a stress relieving layer between the first semiconductor layer 23 and the lower electrode 2 and thus also serves to reduce cracking and delamination in the first semiconductor layer 23. In addition, when forming the insulating layer 26 to a pattern, it can be readily accomplished by ink jet coating, for example, and therefore the productivity is improved. In the case where the insulating layer 26 includes a polyimide resin, the total content of the polyimide resin is preferably greater than or equal to 50 mass % relative to the total mass of the insulating layer 26. When it is intended to further increase the flexibility and thermal resistance of the insulating layer 26, the total content of the polyimide resin is preferably greater than or equal to 70 mass % relative to the total mass of the insulating layer 26.

The insulating layer 26 may have a thickness of approximately 15 to 200 nm. In order to further increase the photoelectric conversion efficiency by performing passivation function via the insulating layer 26 and sufficiently extracting carriers, the area of the junction between the intermediate layer 23a and the first semiconductor layer 23 may be from 0.01 to 2 times the area of the junction between the insulating layer 26 and the first semiconductor layer 23.

Examples of film deposition processes for forming the insulating layer 26 include vapor deposition, sputtering, sol-gel processing, screen printing, coating, plating, spray coating, ink jet coating, and ALD. Optionally, in addition to the above, a pattern-forming process may be employed to form the insulating layer 26 to a desired pattern. Examples of the process include photolithography, lift-off, coating using a dispenser, and laser scribing.

The number and the size of the insulating layer 26 may be varied from region to region. As a result, the insulating layer 26 can conform to the composition of the first semiconductor layer 23 and film thickness variations thereof to enhance the effect of inhibiting recombination, and can reduce the resistance component as much as possible to increase the conversion efficiency of the photoelectric conversion device 21.

### Photoelectric Conversion Device According to Third Embodiment

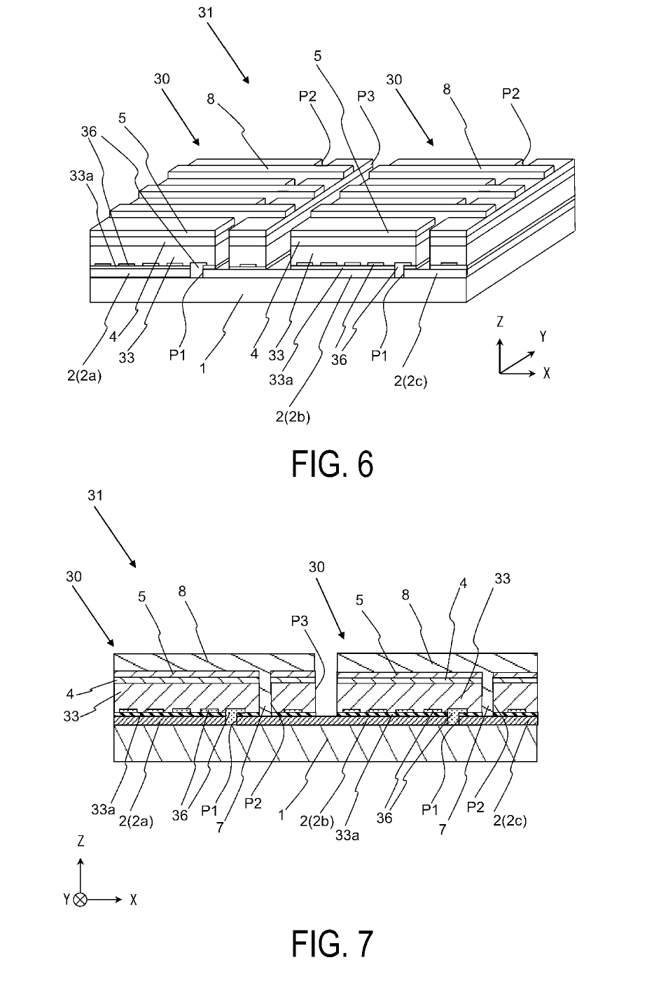

FIG. 6 is a perspective view of a photoelectric conversion device 31 according to a third embodiment, and FIG. 7 is a sectional view thereof. In the photoelectric conversion device 31 according to the third embodiment, the same parts as those in the photoelectric conversion device 11 according to the first embodiment are indicated by the same reference signs, and detailed descriptions thereof will not be provided.

In each of the photoelectric cells 30 of the photoelectric conversion device 31 according to the third embodiment, an insulating layer 36 is located at the interface between an intermediate layer 33a and a first semiconductor layer 33. The insulating layer 36 partially covers the intermediate layer 33a. The first semiconductor layer 33 is joined to the intermediate layer 33a and the insulating layer 36.

With this configuration, the insulating layer 36 serves as a passivation film and produces a field effect due to band bending, to thereby reduce recombination of carriers at the surface of the first semiconductor layer 33 is reduced. In the region where the insulating layer 36 is not present, the intermediate layer 33a can sufficiently extract carriers from the first semiconductor layer 33. As a result of the above, the photoelectric conversion efficiency of the photoelectric conversion device 31 is further improved.

The photoelectric conversion device 31 according to the third embodiment can be formed as follows. The intermediate layer 33a may be formed over the entire area of the lower electrode layer 2 and then the insulating layer 36 may be formed without the need to perform a patterning process such as removal of the intermediate layer 33a. As a result, the production process is simplified.

The insulating layer 36 may be configured similarly to the insulating layer 26 of the photoelectric conversion device 21 according to the second embodiment and may include similar materials to those of the insulating layer 26.

### REFERENCE SIGNS LIST

2, 2a, 2b, 2c Lower electrode layer

3, 23, 33 First semiconductor layer

3a, 23a, 33a Intermediate layer

4 Buffer layer

5 Upper electrode layer

26, 36 Insulating layer

11, 21, 31 Photoelectric conversion device

1. A photoelectric conversion device comprising:
an electrode layer;
a first semiconductor layer over the electrode layer, the first semiconductor layer comprising primarily a chalcopyrite-type compound or a perovskite-type compound, and the first semiconductor layer having p-type or i-type conductivity;
a second semiconductor layer over the first semiconductor layer, the second semiconductor layer having n-type conductivity; and
an intermediate layer at an interface between the electrode layer and the first semiconductor layer, the intermediate layer comprising primarily a semiconductor having p-type conductivity and having a crystal structure different from a crystal structure of the first semiconductor layer, the intermediate layer having a carrier concentration greater than a carrier concentration of the first semiconductor layer.

2. The photoelectric conversion device according to claim 1, wherein the intermediate layer comprises primarily silicon.

3. The photoelectric conversion device according to claim 1, wherein the carrier concentration of the first semiconductor layer ranges from 1×10¹⁰ to 9×10¹⁷ cm⁻³ and the carrier concentration of the intermediate layer ranges from 1×10¹⁸ to 9×10¹⁸ cm⁻³.

4. The photoelectric conversion device according to claim 1, wherein
the intermediate layer partially covers the electrode layer,
the photoelectric conversion device further comprises an insulating layer covering a region of the electrode layer that is not covered by the intermediate layer, and
the first semiconductor layer is joined to the intermediate layer and the insulating layer.

5. The photoelectric conversion device according to claim 1, wherein
the photoelectric conversion device further comprises an insulating layer at an interface between the intermediate layer and the first semiconductor layer, the insulating layer partially covering the intermediate layer, and
the first semiconductor layer is joined to the intermediate layer and the insulating layer.

6. The photoelectric conversion device according to claim 4, wherein the insulating layer has an electrical resistivity of greater than or equal to 1 Ω·m.

7. The photoelectric conversion device according to claim 4, wherein an area of a junction between the intermediate layer and the first semiconductor layer is from 0.01 to 2 times an area of a junction between the insulating layer and the first semiconductor layer.

8. The photoelectric conversion device according to claim 5, wherein the insulating layer has an electrical resistivity of greater than or equal to 1 Ω·m.

9. The photoelectric conversion device according to claim 5, wherein an area of a junction between the intermediate layer and the first semiconductor layer is from 0.01 to 2 times an area of a junction between the insulating layer and the first semiconductor layer.

10. The photoelectric conversion device according to claim 6, wherein an area of a junction between the intermediate layer and the first semiconductor layer is from 0.01 to 2 times an area of a junction between the insulating layer and the first semiconductor layer.

11. The photoelectric conversion device according to claim 4, wherein the intermediate layer comprises primarily silicon.

12. The photoelectric conversion device according to claim 5, wherein the intermediate layer comprises primarily silicon.
